(19) United States
(12) Patent Application Publication
(10) Pub. No.: US 2024/0292597 A1
(43) Pub. Date: Aug. 29, 2024

(54) SEMICONDUCTOR DEVICE AND METHOD OF FABRICATING THE SAME

(71) Applicant: Samsung Electronics Co., Ltd., Suwon-si (KR)

(72) Inventors: Junghwan HUH, Suwon-si (KR); Daehyun KIM, Suwon-si (KR); Yeajin NA, Suwon-si (KR); Junsik YU, Suwon-si (KR); Taekyung YOON, Suwon-si (KR); Yoojin JEONG, Suwon-si (KR); Yongjun CHOI, Suwon-si (KR)

(73) Assignee: Samsung Electronics Co., Ltd., Suwon-si (KR)

(21) Appl. No.: 18/528,621

(22) Filed: Dec. 4, 2023

(30) Foreign Application Priority Data
Feb. 27, 2023 (KR) 10-2023-0026145

(51) Int. Cl. H10B 12/00

(52) U.S. Cl. CPC H10B 12/315; H10B 12/485; H10B 12/482

(57) ABSTRACT

Described is a semiconductor device comprising an active pattern, an additional active layer on the active pattern, and a gate structure that runs across the active pattern. The additional active layer includes a bottom surface connected to a sidewall of the active pattern and an upper curved surface at a level higher than a level of the bottom surface. A lattice contact of the additional active layer is different from that of the active pattern.

### CROSS-REFERENCE TO RELATED APPLICATION

This U.S. nonprovisional application claims priority under 35 U.S.C § 119 to Korean Patent Application No. 10-2023-0026145 filed on Feb. 27, 2023 in the Korean Intellectual Property Office, the disclosure of which is hereby incorporated by reference in its entirety.

### BACKGROUND

The present inventive concepts relate to a semiconductor device and a method of fabricating the same, and more particularly, to a semiconductor device including an additional active layer on a top surface of an active pattern and a method of fabricating the same.

Semiconductor devices have an important role in the electronic industry because of their small size, multi-functionality, and/or low fabrication cost. The semiconductor devices may be categorized as any one of semiconductor memory devices storing logic data, semiconductor logic devices processing operations of logic data, and hybrid semiconductor devices having both memory and logic elements.

### SUMMARY

Some example embodiments of the present inventive concepts provide a method of fabricating a semiconductor device with improved electrical properties.

Some example embodiments of the present inventive concepts provide a method of fabricating a semiconductor device with increased reliability.

Example embodiments of the present inventive concepts not limited to the mentioned above, and other example embodiments which have not been mentioned above will be clearly understood to those skilled in the art from the following description.

According to some example embodiments of the present inventive concepts, a semiconductor device may comprise: an active pattern; an additional active layer on the active pattern; and a gate structure that runs across the active pattern. The additional active layer may include: a bottom surface connected to a sidewall of the active pattern; and an upper curved surface at a level higher than a level of the bottom surface. A lattice constant of the additional active layer may be different from a lattice constant of the active pattern.

According to some example embodiments of the present inventive concepts, a semiconductor device may comprise: an active pattern; an additional active layer on the active pattern; and a storage node contact in contact with the additional active layer and the active pattern. The additional active layer may include: a bottom surface connected to a sidewall of the active pattern; an upper curved surface at a level higher than a level of the bottom surface; and a lateral surface between the bottom surface and the upper curved surface. The additional active layer may include a first contact point in contact with the sidewall of the active pattern. The first contact point may be at a level lower than a level of a lowermost portion of the storage node contact.

According to some example embodiments of the present inventive concepts, a semiconductor device may comprise: an active pattern; an additional active layer on the active pattern; a device isolation pattern that surrounds the active pattern; and a storage node contact electrically connected to the additional active layer. The additional active layer may include a bottom surface connected to a sidewall of the active pattern. A contact point may be at which the bottom surface of the additional active layer is in contact with the sidewall of the active pattern. The contact point may be at a level lower than a level of a lowermost portion of the storage node contact. A lattice constant of the additional active layer may be different from a lattice constant of the active pattern.

### BRIEF DESCRIPTION OF DRAWINGS

FIGS. 1 and 6 illustrate plan views showing a semiconductor device according to some example embodiments of the present inventive concepts.

FIG. 2 illustrates a cross-sectional view taken along line A-A′ of FIG. 1.

FIG. 3 illustrates a cross-sectional view taken along line B-B′ of FIG. 1.

FIG. 4 illustrates a cross-sectional view taken along line C-C′ of FIG. 1.

FIG. 5 illustrates a cross-sectional view taken along line D-D′ of FIG. 1.

FIG. 7 illustrates an enlarged view showing section Q of FIG. 6.

FIG. 8 illustrates an enlarged view showing section S of FIG. 2.

FIG. 9 illustrates an enlarged view showing section P of FIG. 5.

FIGS. 10, 15, 20, 25, 30, 35, and 40 illustrate plan views showing a method of fabricating a semiconductor device according to some example embodiments of the present inventive concepts.

FIGS. 11, 16, 21, 26, 31, 36, and 41 illustrate cross-sectional views taken along line A-A′ of FIGS. 10, 15, 20, 25, 30, 35, and 40, respectively.

FIGS. 12, 17, 22, 27, 32, 37, and 42 illustrate cross-sectional views taken along line B-B′ of FIGS. 10, 15, 20, 25, 30, 35, and 40, respectively.

FIGS. 13, 18, 23, 28, 33, 38, and 43 illustrate cross-sectional views taken along line C-C′ of FIGS. 10, 15, 20, 25, 30, 35, and 40, respectively.

FIGS. 14, 19, 24, 29, 34, 39, and 44 illustrate cross-sectional views taken along line D-D′ of FIGS. 10, 15, 20, 25, 30, 35, and 40, respectively.

FIG. 45 illustrates a plan view showing a semiconductor device according to some example embodiments of the present inventive concepts.

FIG. 46 illustrates a cross-sectional view taken along line A-A′ of FIG. 45.

FIG. 47 illustrates a cross-sectional view taken along line B-B′ of FIG. 45.

FIG. 48 illustrates a cross-sectional view taken along line C-C′ of FIG. 45.

FIG. 49 illustrates a cross-sectional view taken along line D-D′ of FIG. 45.

### DETAILED DESCRIPTION OF EMBODIMENTS

Some example embodiments of the present inventive concepts will now be described in detail with reference to the accompanying drawings to aid in clearly explaining the present inventive concepts.

It will be understood that expressions such as “at least one of,” when preceding a list of elements, modify the entire list of elements and do not modify the individual elements of the list. For example, such as “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%).

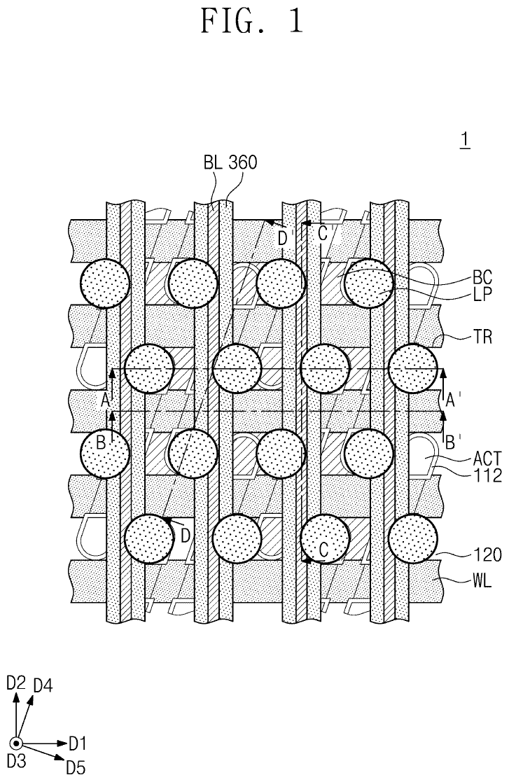

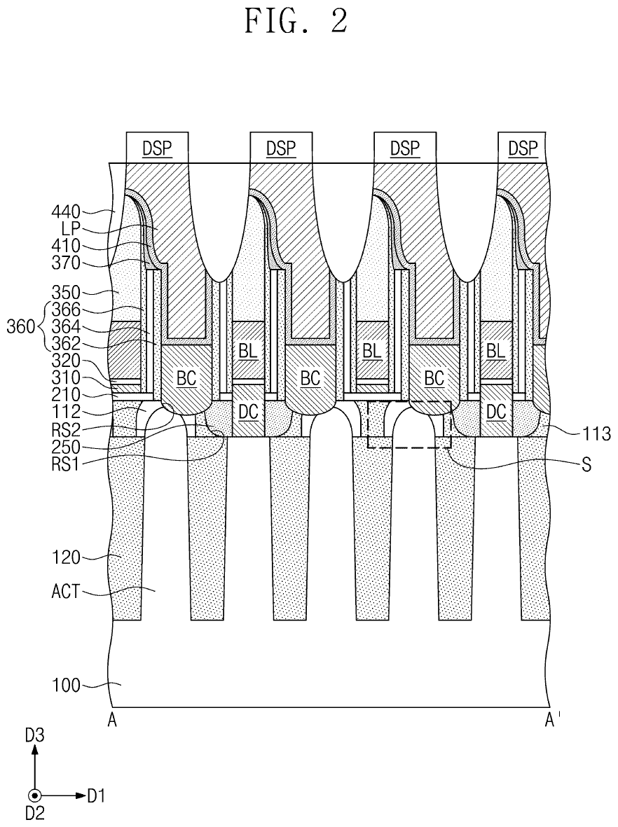

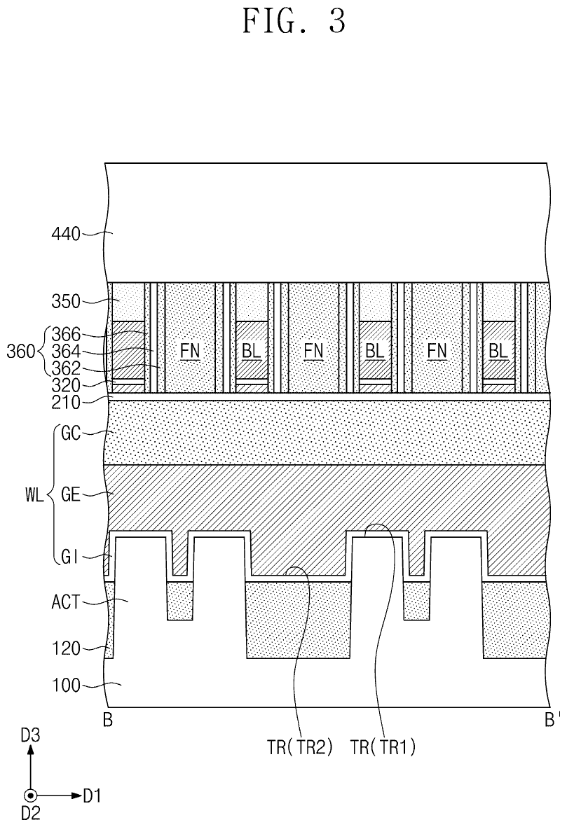

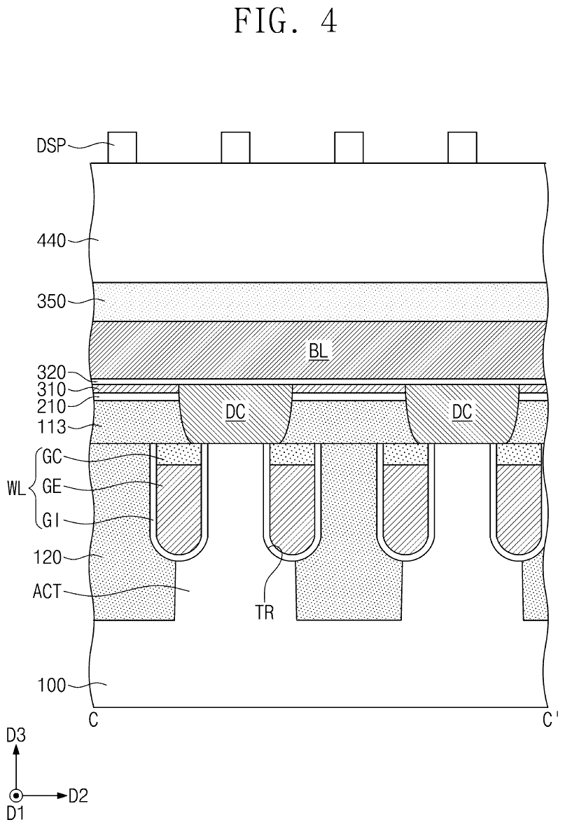

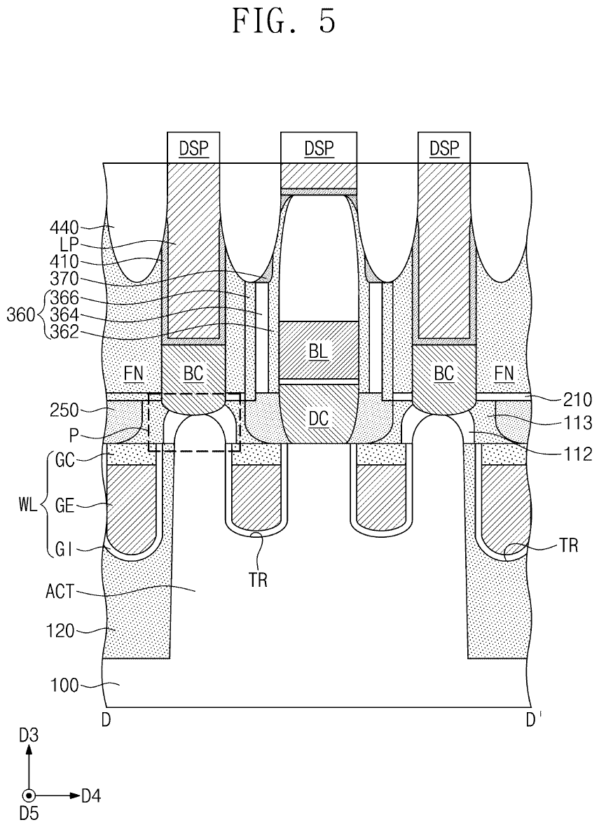

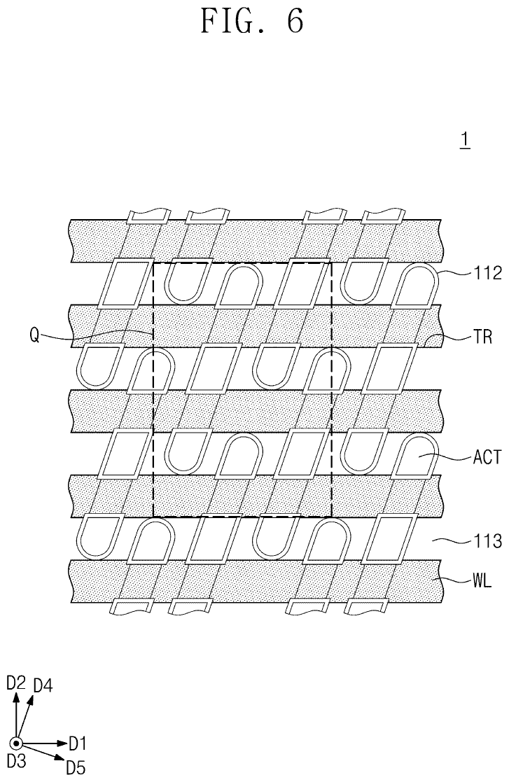

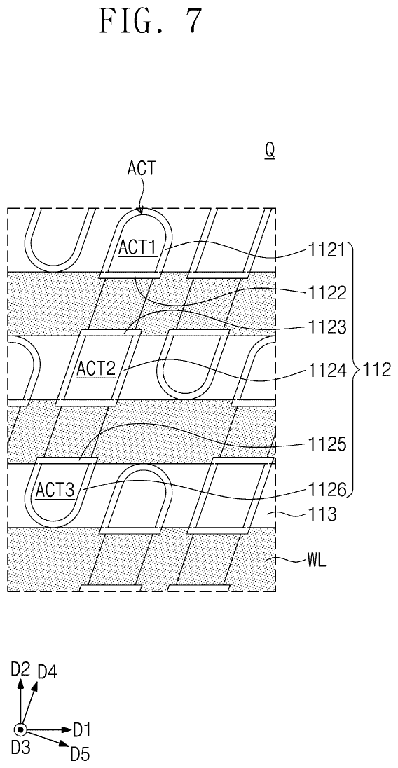

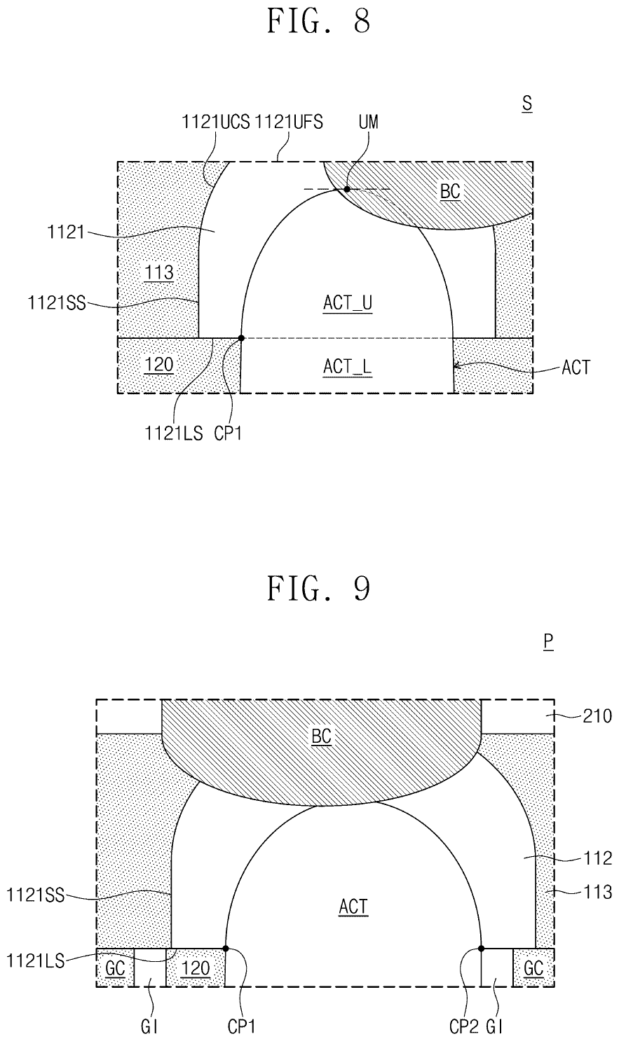

FIGS. 1 and 6 illustrate plan views showing a semiconductor device according to some example embodiments of the present inventive concepts. FIG. 2 illustrates a cross-sectional view taken along line A-A′ of FIG. 1. FIG. 3 illustrates a cross-sectional view taken along line B-B′ of FIG. 1. FIG. 4 illustrates a cross-sectional view taken along line C-C′ of FIG. 1. FIG. 5 illustrates a cross-sectional view taken along line D-D′ of FIG. 1. FIG. 7 illustrates an enlarged view showing section Q of FIG. 6. FIG. 8 illustrates an enlarged view showing section S of FIG. 2. FIG. 9 illustrates an enlarged view showing section P of FIG. 5.

To help in understanding of some example embodiments of the present inventive concepts, FIG. 6 illustrates only structures of components positioned below an active pattern ACT which will be discussed below. Although not shown, it should therefore be understood that FIG. 6, like FIG. 1, illustrates components positioned above an active pattern ACT which will be discussed below.

Referring to FIGS. 2 to 5, a semiconductor 1 may include a substrate 100. The substrate 100 may be a semiconductor substrate. For example, the substrate 100 may include silicon (Si), germanium (Ge), silicon-germanium (SiGe), gallium phosphide (GaP), or gallium arsenide (GaAs). In some example embodiments, the substrate 100 may be a silicon-on-insulator (SOI) substrate or a germanium-on-insulator (GOI) substrate. The substrate 100 may have a plate shape that extends along a plane elongated in a first direction D1 and a second direction D2. The first direction D1 and the second direction D2 may intersect each other. The first direction D1 and the second direction D2 may be, for example, horizontal directions that are orthogonal to each other.

The substrate 100 may include active patterns ACT. The active patterns ACT may be defined to indicate upper portions of the substrate 100 that protrude in a third direction D3. The active patterns ACT may be spaced apart from each other in a fourth direction D4 and a fifth direction D5. The active pattern ACT may include the same material as that of the substrate 100.

A device isolation pattern 120 may be provided in a space provided between the active patterns ACT. The device isolation pattern 120 may be provided in the substrate 100. The active patterns ACT may be defined by the device isolation pattern 120. At least one of the active patterns ACT may be surrounded by the device isolation pattern 120. The device isolation pattern 120 may include a dielectric material. For example, the device isolation pattern 120 may include at least one of silicon oxide, silicon nitride, or any combination thereof. The device isolation pattern 120 may be a single layer formed of one material or a composite layer formed of two or more materials. In this description, each of the languages “A or B”, “at least one of A and B”, “at least one A or B”, “A, B, or C”, “at least one of A, B, and C”, and “at least one A, B, or C” may include one or any possible combination of elements listed in a corresponding one of the expressions mentioned above.

In some example embodiments, gate structure WL may run across the active patterns ACT. The gate structure WL may be provided in plural. The plurality of gate structures WL may each extend in the first direction D1 and may be spaced apart from each other in the second direction D2. Each of the first direction D1 and the second direction D2 may be parallel or substantially parallel to a bottom surface of the substrate 100, and may intersect the fourth and fifth directions D4 and D5. The gate structures WL may be disposed don trenches TR provided in the active patterns ACT and the device isolation pattern 120. For example, a pair of gate structures WL that neighbor each other in the second direction D2 may run across a single active pattern ACT.

Each of the gate structures WL may include a gate electrode GE, a gate dielectric pattern GI, and a gate capping pattern GC. The gate electrode GE may penetrate in the first direction D1 through the active patterns ACT and the device isolation pattern 120. The gate dielectric pattern GI may be interposed between the gate electrode GE and the active patterns ACT and between the gate electrode GE and the device isolation pattern 120. The gate electrode GE may be provided on dielectric layer with the gate capping pattern GC that at least partially covers a top surface of the gate electrode. The gate electrode GE may include, for example, a conductive material. The gate dielectric pattern GI may include, for example, at least one of silicon oxide and high-k dielectrics. The gate capping pattern GP may include, for example, silicon nitride.

An additional active layer 112 may be provided on the active pattern ACT. The additional active layer 112 may be in contact with the active pattern ACT. The additional active layer 112 may have a lattice constant different from that of the active pattern ACT.

When viewed in plan, the additional active layer 112 may surround the active pattern ACT. When viewed in plan, the additional active layer 112 may at least partially overlap the gate structure WL. The additional active layer 112 may at least partially overlap the device isolation pattern 120. The additional active layer 112 may at least partially overlap a storage node contact BC which will be discussed below. The additional active layer 112 may contact a storage node contact BC which will be discussed below. The additional active layer 112 may at least partially overlap the gate capping pattern GC. A lowermost portion of the additional active layer 112 may be located at a level lower than that of a lowermost portion of a storage node contact BC, which will be discussed below. In an example embodiment, a bottom surface of the additional active layer 112 may be located at a level higher (e.g., above) than that of a bottom surface of a bit-line contact DC which will be discussed below.

A additional capping layer 113 may be provided on the gate capping pattern GC and the device isolation pattern 120. The additional capping layer 113 may be provided on the gate capping pattern GC. An interface may be formed between the gate capping pattern GC and the additional capping layer 113. In some example embodiments, the additional capping layer 113, the device isolation pattern 120, and the gate capping pattern GC may include the same dielectric material. For example, the additional capping layer 113, the device isolation pattern 120, and the gate capping pattern GC may include silicon nitride. In some example embodiments, the additional capping layer 113, the device isolation pattern 120, and the gate capping pattern GC may include different dielectric materials from each other.

The additional capping layer 113 may be in contact with a buried dielectric pattern 250 which will be discussed below. The additional capping layer 113 may be in contact with the additional active layer 112. The additional capping layer 113 may at least partially cover a lateral surface of the additional active layer 112. The additional capping layer 113 may be in contact with the lateral surface of the additional active layer 112. A lowermost portion of the additional capping layer 113 may be located at a level the same as (e.g., planar with) that of the lowermost portion of the additional active layer 112. The level of the lowermost portion of the additional capping layer 113 may be the same as that of a top surface of the gate dielectric pattern GI.

A buffer pattern 210 may be disposed on the substrate 100. The buffer pattern 210 may at least partially cover the active patterns ACT, the additional capping layer 113, and the additional active layer 112. For example, the buffer pattern 210 may include at least one of silicon oxide, silicon nitride, silicon oxynitride, or any combination thereof. The buffer pattern 210 may be a single layer formed of one material or a composite layer formed of two or more materials.

A bit-line contact DC may be provided on each of the active patterns ACT, and may be provided in plural. The plurality of bit-line contacts DC may be correspondingly electrically connected to central active patterns CA of the active patterns ACT. The bit-line contacts DC may be spaced apart from each other in the first and second directions D1 and D2. The bit-line contacts DC may be correspondingly interposed between the active patterns ACT and bit lines BL which will be discussed below. The bit-line contacts DC may electrically connect the bit line BL to a subsequently described second active part ACT2 of corresponding active patterns ACT, described below

The bit-line contacts DC may be correspondingly disposed in first recesses RS1. The first recesses RS1 may be provided on upper portions of the active patterns ACT and an upper portion of the device isolation pattern 120 adjacent to the upper portions of the active patterns ACT. The first recesses RS1 may be spaced apart from each other in the first and second directions D1 and D2.

A buried dielectric pattern 250 may fill each of the first recesses RS1. The buried dielectric pattern 250 may fill an inside of the first recess RS1. For example, the buried dielectric pattern 250 may at least partially cover an inner surface of the first recess RS1 and at least a portion of a lateral surface of the bit-line contact (e.g., at least a portion of a lateral surface of the bit-line contact DC in the first recess RS1). The buried dielectric pattern 250 may include at least one of silicon oxide, silicon nitride, or any combination thereof. The buried dielectric pattern 250 may be a single layer formed of one material or a composite layer formed of two or more materials.

A bit line BL may be provided on the bit-line contact DC. The bit line BL may extend along the second direction D2. The bit line BL may be disposed on a series of bit-line contacts DC that are arranged along the second direction D2. The bit line BL may be provided in plural. The plurality of bit lines BL may be spaced apart from each other in the first direction D1. The bit line BL may include a metallic material. For example, the bit line BL may include at least one of tungsten, rubidium, molybdenum, titanium, or any combination thereof.

An intervening pattern 310 may be provided between the bit line BL and the buffer pattern 210. The intervening pattern 310 may be provided in plural. The plurality of intervening patterns 310 may be spaced apart from each other in the first direction D1 and the second direction D2. The intervening pattern 310 and the bit-line contact DC may have their top surfaces that are located at the same or substantially the same height (level), e.g., coplanar or substantially coplanar with each other. The intervening pattern 310 may include impurity-doped polysilicon.

A first ohmic pattern 320 may be interposed between the bit line BL and the bit-line contact DC and between the bit line BL and the intervening pattern 310. The first ohmic pattern 320 may extend in the second direction D2 along the bit line BL. The first ohmic pattern 320 may be provided in plural. The plurality of first ohmic patterns 320 may be spaced apart from each other in the first direction D1. The first ohmic pattern 320 may include metal silicide. A first barrier pattern (not shown) may further be interposed between the bit line BL and the bit-line contact DC and between the bit line BL and the intervening pattern 310. The first barrier pattern may include conductive metal nitride, such as titanium nitride and tantalum nitride.

A bit-line capping pattern 350 may be provided on a top surface of the bit line BL. The bit-line capping pattern 350 may extend in the second direction D2 on the top surface of the bit line BL. The bit-line capping pattern 350 may be provided in plural. The plurality of bit-line capping patterns 350 may be spaced apart from each other in the first direction D1. The bit-line capping pattern 350 may at least partially vertically overlap the bit line BL. The bit-line capping pattern 350 may be formed of a single or multiple layer.

A bit-line spacer 360 may be provided on a lateral surface of the bit line BL and a lateral surface of the bit-line capping pattern 350. The bit-line spacer 360 may at least partially cover the lateral surface of the bit line BL and the lateral surface of the bit-line capping pattern 350. The bit-line spacer 360 may extend along the second direction D2 on the lateral surface of the bit line BL.

The bit-line spacer 360 may include a plurality of spacers. For example, the bit-line spacer 360 may include a first spacer 362, a second spacer 364, and a third spacer 366. The third spacer 366 may be provided on the lateral surface of the bit line BL and the lateral surface of the bit-line capping pattern 350. The first spacer 362 may be interposed between the second spacer 364 and a storage node contact BC which will be discussed below. The second spacer 364 may be interposed between the first spacer 362 and the third spacer 366. For example, each of the first, second, and third spacers 362, 364, and 366 may independently include at least one of silicon nitride, silicon oxide, silicon oxynitride, or any combination thereof. For another example, the second spacer 364 may include a kind of air gap that separates the first and third spacers 362 and 366 from each other.

A capping spacer 370 may be positioned on the bit-line spacer 360. The capping spacer 370 may at least partially cover an upper portion of a lateral surface of the bit-line spacer 360. The capping spacer 370 may include, for example, silicon nitride.

A storage node contact BC may be provided between neighboring (e.g., adjacent) bit lines BL. For example, the storage node contact BC may be interposed between neighboring bit-line spacers 360. The storage node contact BC may be provided in plural. The plurality of storage node contacts BC may be spaced apart from each other in the first and second directions D1 and D2. The storage node contacts BC may be spaced apart in the second direction D2 from each other by fence patterns FN on the gate structures WL. The fence pattern FN may be provided between neighboring bit lines BL. The fence pattern FN may be provided in plural. The plurality of fence patterns FN may be spaced apart from each other in the first and second directions D1 and D2. The fence patterns FN that neighbor each other in the first direction D1 may be spaced apart from each other across the bit line BL. The fence patterns FN that neighbor each other in the second direction D2 may be spaced apart from each other across the storage node contact BC. The fence patterns FN may include, for example, silicon nitride.

The storage node contacts BC may correspondingly fill second recesses RS2 provided on first and third active parts ACT1 and ACT3 of the active pattern ACT which will be discussed below. Each of the storage node contacts BC may be electrically connected to one of corresponding first and third active parts ACT1 and ACT3. The storage node contact BC may include at least one of impurity-doped polysilicon, impurity-doped polysilicon, metallic materials, or any combination thereof.

A second barrier pattern 410 may at least partially conformally cover the bit-line spacer 360, the fence pattern FN, and the storage node contact BC. The second barrier pattern 410 may include metal nitride, such as titanium nitride and tantalum nitride. A second ohmic pattern (not shown) may further be interposed between the second barrier pattern 410 and the storage node contact BC. The second ohmic pattern may include, for example, metal silicide.

A landing pad LP may be provided on the storage node contact BC. The landing pad LP may be provided in plural. The plurality of landing pads LP may be spaced apart from each other in the first and second directions D1 and D2. The landing pad LP may be connected to the storage node contact BC that corresponds thereto. The landing pad LP may at least partially cover a top surface of the bit-line capping pattern 350. A lower region of the landing pad LP may at least partially vertically overlap the storage node contact BC. An upper portion of the landing pad LP may be shifted in the fourth direction D4 from the lower portion thereof. The landing pad LP may include a metallic material, such as tungsten, titanium, and tantalum.

A filling pattern 440 may surround the landing pad LP. The filling pattern 440 may be interposed between neighboring landing pads LP. When viewed in plan, the landing pads LP may cause the filling pattern 440 to have a mesh shape including through holes. The filling pattern 440 may include, for example, at least one of silicon nitride, silicon oxide, silicon oxynitride, or any combination thereof. Alternatively, the filling pattern 440 may include an empty space (or air gap) including an air layer.

A data storage pattern DSP may be provided on the landing pad LP. The data storage pattern DSP may be provided in plural. The plurality of data storage patterns DSP may be spaced apart from each other in the first and second directions D1 and D2. Each of the data storage patterns DSP may be electrically connected through a corresponding landing pad LP and a corresponding storage node contact BC to one of corresponding first and second active parts ACT1 and ACT3.

The data storage pattern DSP may be, for example, a capacitor including a bottom electrode, a dielectric layer, and a top electrode. In this case, a semiconductor memory device according to some example embodiments may be a dynamic random access memory (DRAM). For another example, the data storage pattern DSP may include a magnetic tunnel junction pattern. In this case, a semiconductor memory device according to some example embodiments may be a magnetic random access memory (MRAM). For another example, the data storage pattern DSP may include a phase change material or a variable resistance material. In this case, a semiconductor memory device according to some example embodiments may be a phase change random access memory (PRAM) or a resistive random access memory (ReRAM). This is, however, merely an example, and example embodiments are not limited thereto. The data storage pattern DSP may include various structures and/or materials capable of storing data.

With reference to FIGS. 6 to 9, the following will further describe in detail structures of the active pattern ACT, the device isolation pattern 120, the additional capping layer 113, the additional active layer 112, and the gate structure WL of a semiconductor device according to some example embodiments of the present inventive concepts.

Referring to FIGS. 6 and 7, the active pattern ACT may have a curved top surface. For example, the active pattern ACT may have a curved top surface on an interface between the gate capping pattern GC and the additional capping layer 113.

The active patterns ACT may include a first active part ACT1, a second active part ACT2, and a third active part ACT3. The first active part ACT1, the second active part ACT2, and the third active part ACT3 may be spaced apart from each other in the fourth direction D4.

The additional active layer 112 may include a first additional active layer 1121, a second additional active layer 1122, a third additional active layer 1123, a fourth additional active layer 1124, a fifth additional active layer 1125, and a sixth additional active layer 1126. The first additional active layer 1121 and the second additional active layer 1122 may surround the first active part ACT1. The third additional active layer 1123 and the fourth additional active layer 1124 may surround the second active part ACT2. The fifth additional active layer 1125 and the sixth additional active layer 1126 may surround the third active part ACT3.

When viewed in plan, the first additional active layer 1121, the fourth additional active layer 1124, and the sixth additional active layer 1126 may be surrounded by the additional capping layer 113. The second additional active layer 1122, the third additional active layer 1123, and the fifth additional active layer 1125 may at least partially overlap the gate structure WL.

The first additional active layer 1121 and the second additional active layer 1122 may be connected with no interface therebetween. The third additional active layer 1123 and the fourth additional active layer 1124 may be connected with no interface. The fifth additional active layer 1125 and the sixth additional active layer 1126 may be connected with no interface.

Referring to FIG. 8, the active pattern ACT may include an upper portion ACT_U and a lower portion ACT_L. The upper portion ACT_U of the active pattern ACT may be defined to indicate the active pattern ACT on a level of a top surface of the device isolation pattern 120. The lower portion ACT_L of the active pattern ACT may be defined to indicate the active pattern ACT below (the level of) the top surface of the device isolation pattern 120. The additional active layer 112 may surround the upper portion ACT_U of the active pattern ACT. The upper portion ACT_U of the active pattern ACT may have a curved shape at a top surface thereof when viewed in vertical section.

The active pattern ACT may include an uppermost part UM. The uppermost portion UM of the active pattern ACT may be defined to indicate a portion at an uppermost level of the upper portion ACT_U of the active pattern ACT.

The first additional active layer 1121 may be in contact with the storage node contact BC. The first additional active layer 1121 may at least partially overlap the storage node contact BC.

The first additional active layer 1121 may be epitaxially grown while being in contact with the active pattern ACT. The first additional active layer 1121 may have a bottom surface 1121LS connected to a sidewall of the active pattern ACT, an upper curved surface 1121UCS located at a level higher than that of the bottom surface 1121LS, an upper flat surface 1121UFS connected to the upper curved surface 1121UCS, and a lateral surface 1121SS between the bottom surface 1121LS and the upper curved surface 1121UCS. The upper curved surface 1121UCS of the first additional active layer 1121 may be curved or substantially curved. The bottom surface 1121LS of the first additional active layer 1121 may be flat or substantially flat. The level of the bottom surface 1121LS of the first additional active layer 1121 may be the same as that of the top surface of the device isolation pattern 120. The level of the bottom surface 1121LS of the first additional active layer 1121 may be the same as that of a top surface of the gate capping pattern GC. The description of the first additional active layer 1121 may hold true of the second to sixth additional active layers 1122 to 1126.

A first contact point CP1 may be defined to refer to a portion where the bottom surface 1121LS of the first additional active layer 1121 is in contact with the sidewall of the active pattern ACT. The first contact point CP1 may be positioned at a level the same as that of a bottom surface of the additional capping layer 113. The first contact point CP1 may be in contact with the device isolation pattern 120. The first contact point CP1 may be in contact with the sidewall of the active pattern ACT. In an example embodiment, the lowermost portion of the additional active layer 112 may be in contact with the gate dielectric pattern GI.

The additional capping layer 113 may at least partially cover the upper curved surface 1121UCS and the lateral surface 1121SS of the additional active layer 112 and a top surface of the gate dielectric pattern GI. The bottom surface of the additional capping layer 113 may be in contact with the top surface of the gate dielectric pattern GI.

Referring to FIG. 9, a second contact point CP2 may be defined to refer to a point where the bottom surface 1121LS of the first additional active layer 1121 is in contact with the active pattern ACT and the gate dielectric pattern GI. The second contact point CP2 may be located at a level the same as that of the lowermost portion of the additional active layer 112. The second contact point CP2 may be located at a level the same as that of the top surface of the gate capping pattern GC. The first contact point CP1 and the second contact point CP2 may be located at a level higher than that of a lowermost portion of the bit-line contact DC and lower than that of the lowermost portion of the storage node contact BC.

The first contact point CP1 may be in contact with the device isolation pattern 120, the active pattern ACT, the additional active layer 112, and the additional capping layer 113. The second contact point CP2 may be in contact with the gate dielectric pattern GI, the active pattern ACT, the additional active layer 112, and the additional capping layer 113.

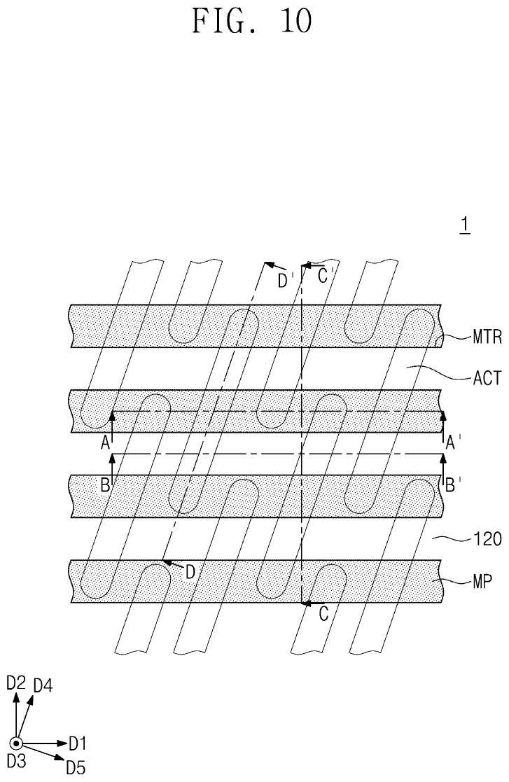

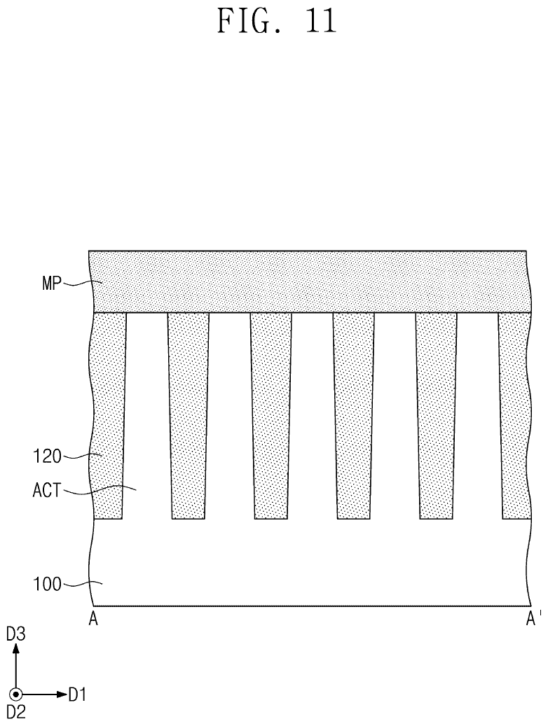

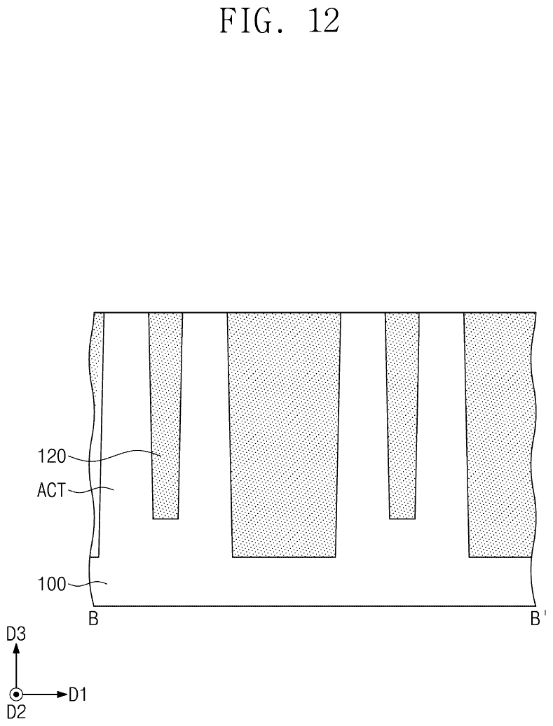

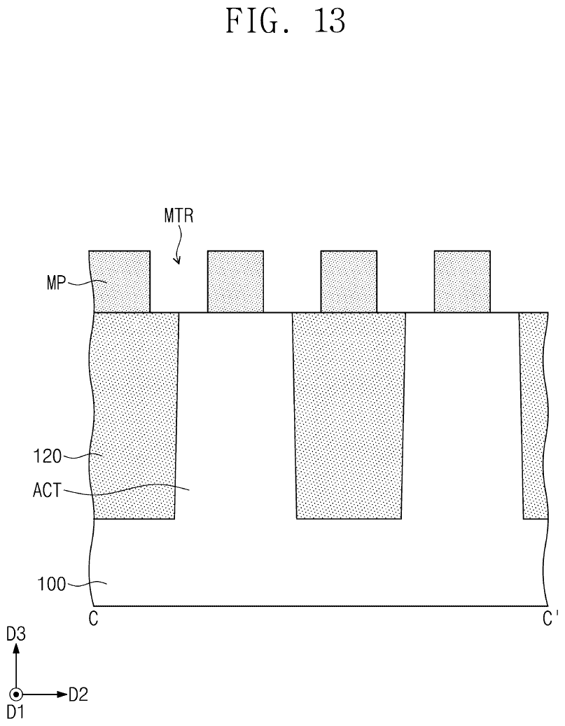

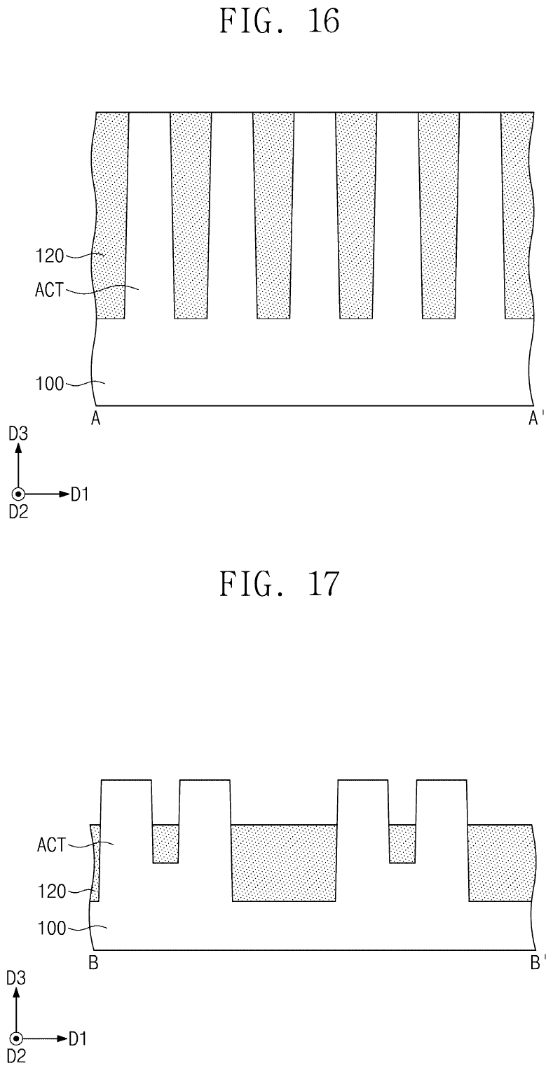

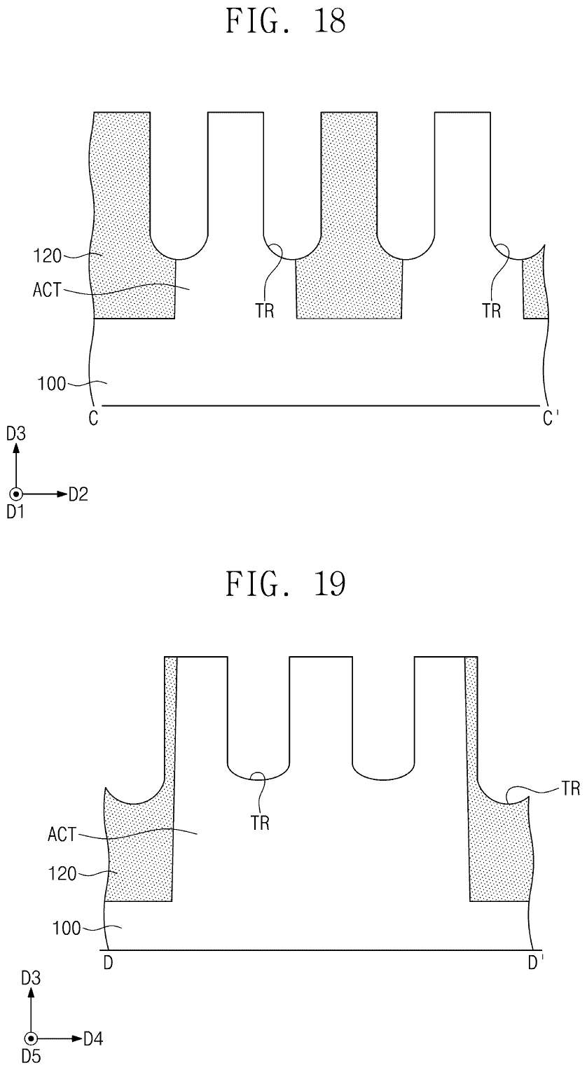

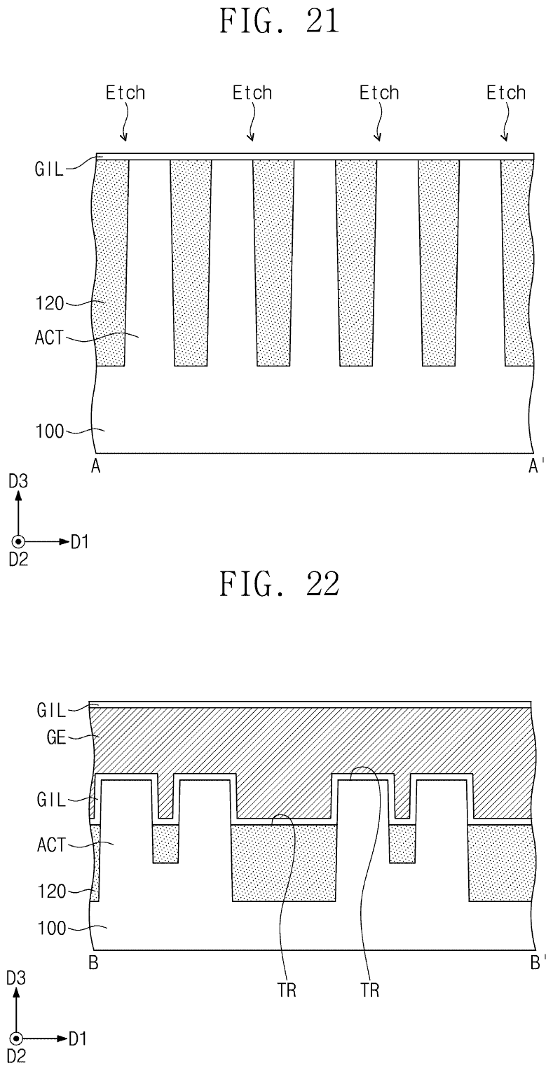

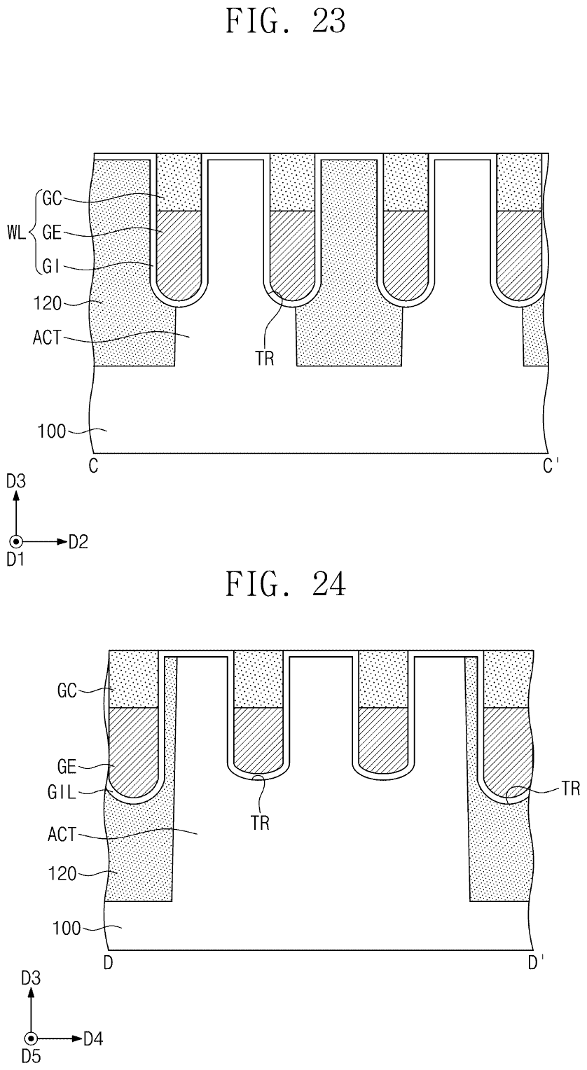

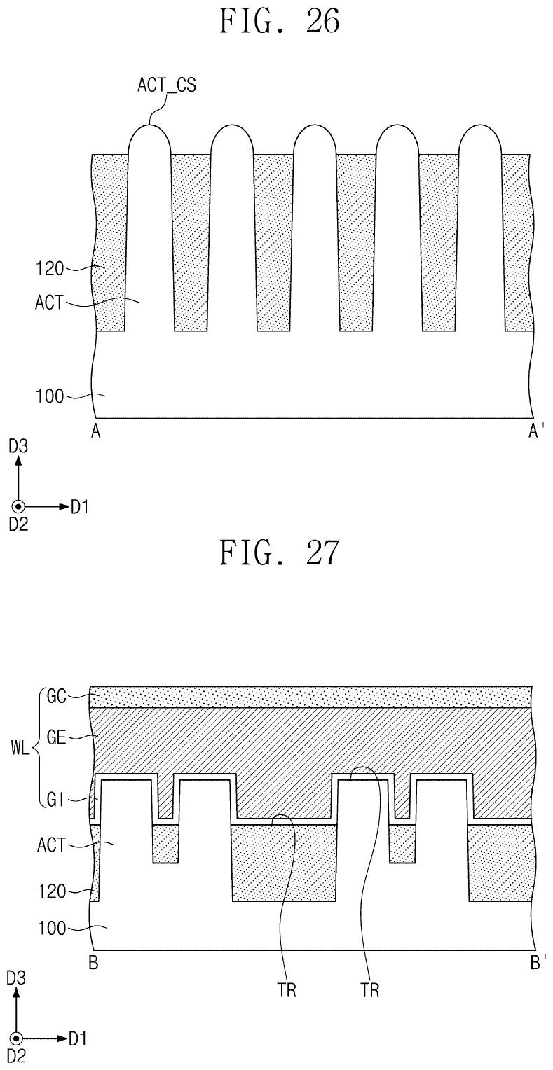

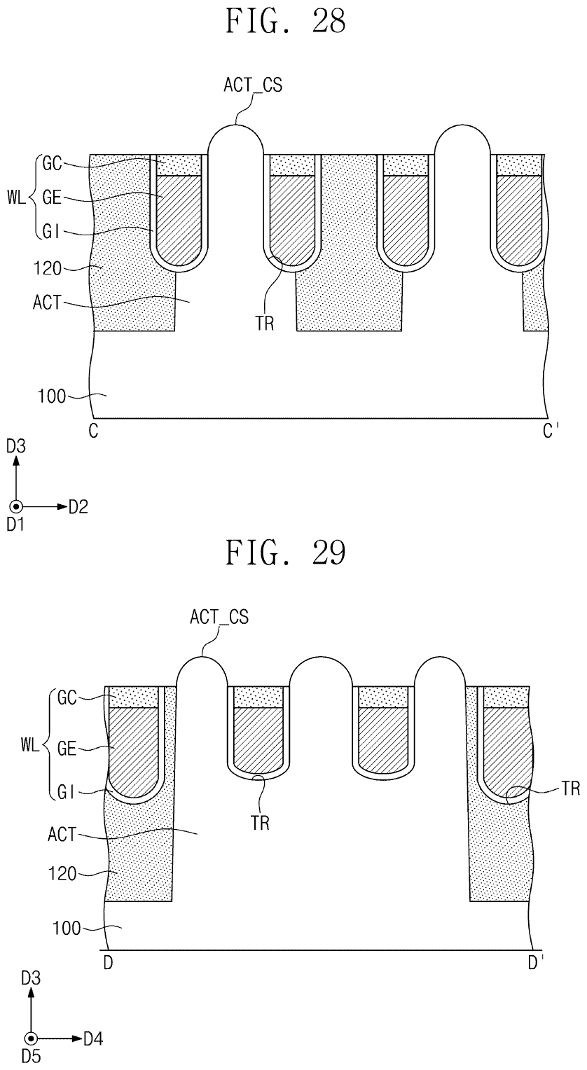

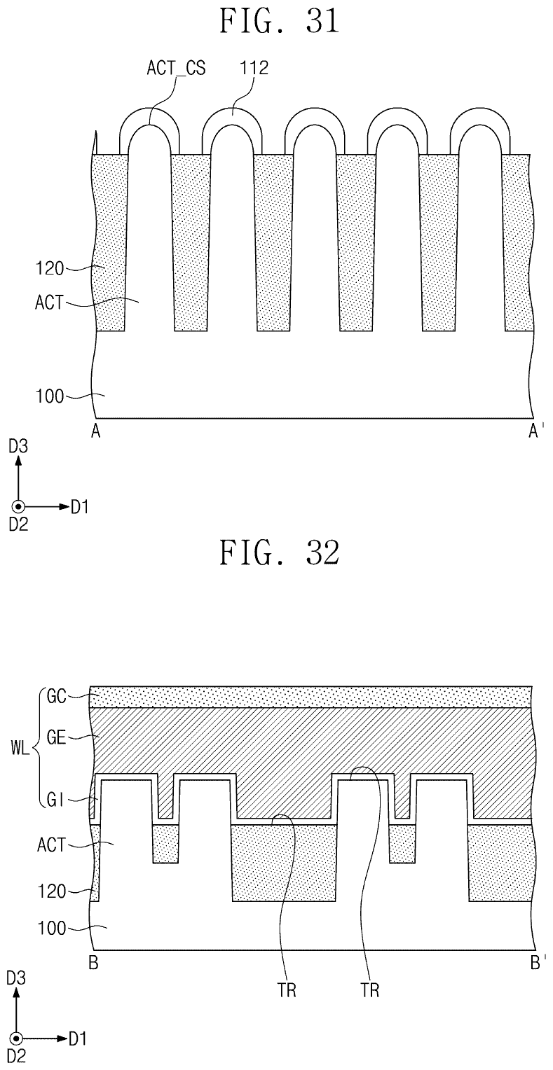

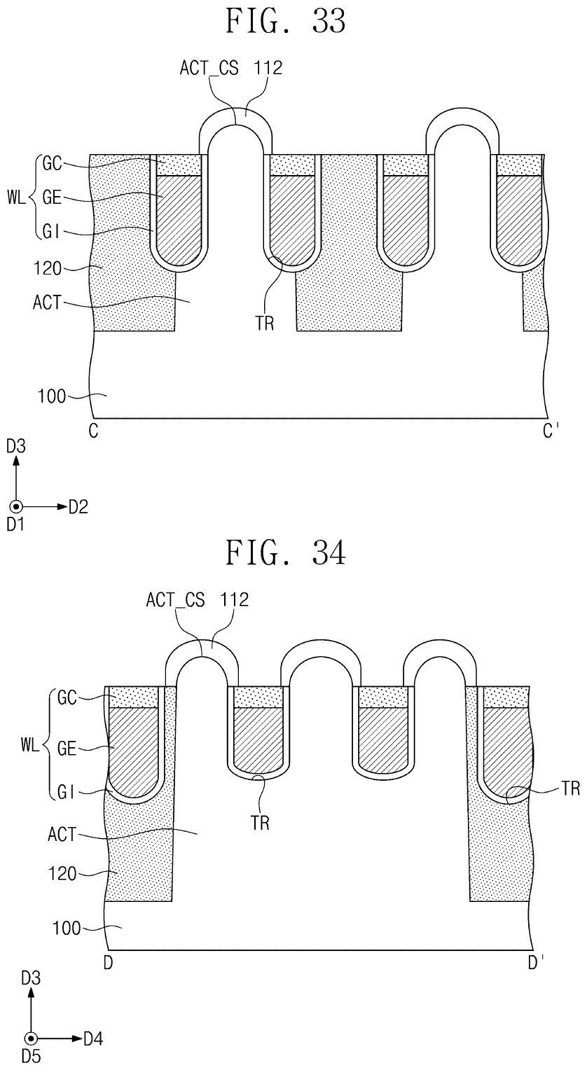

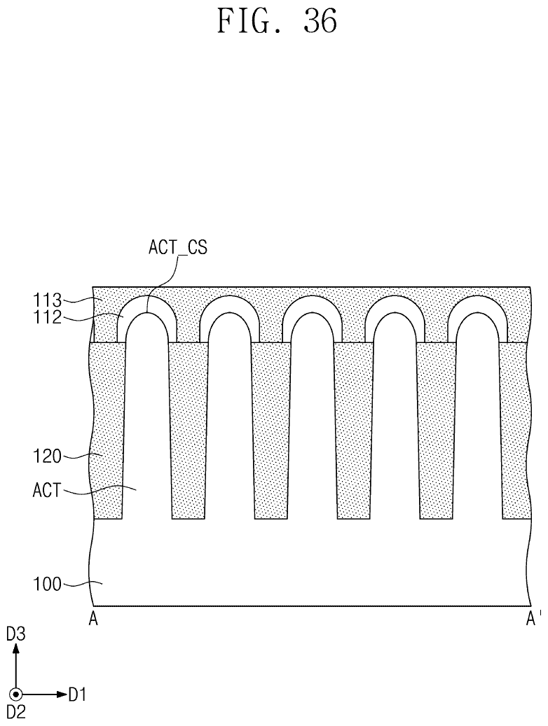

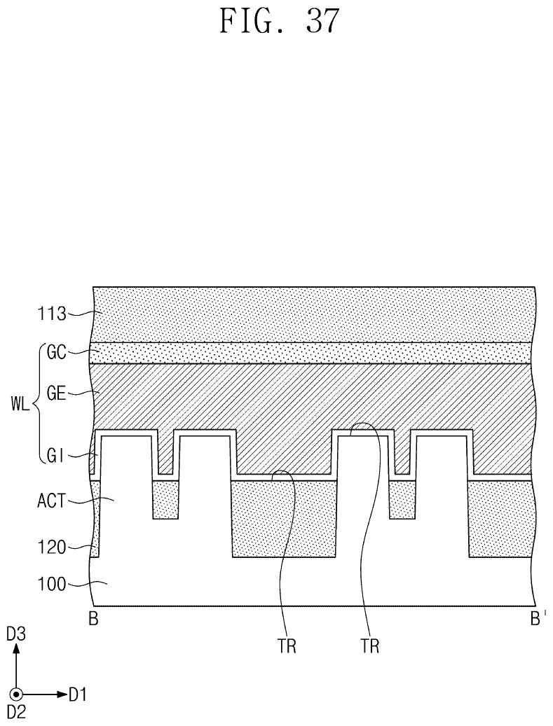

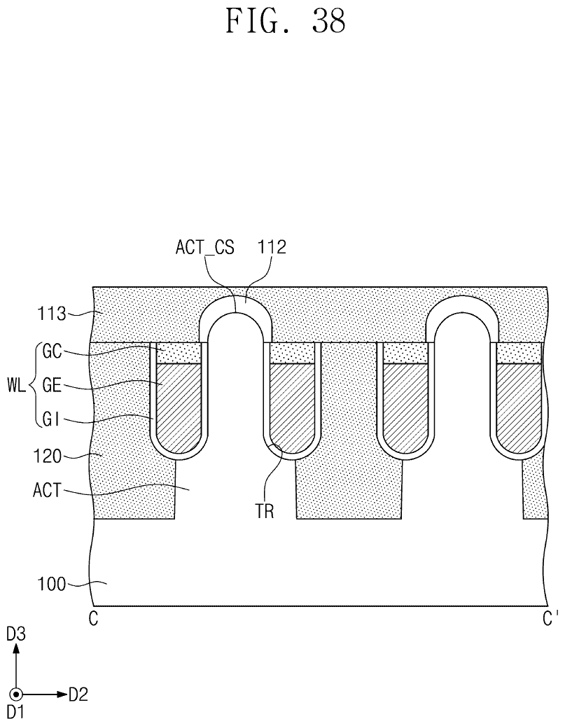

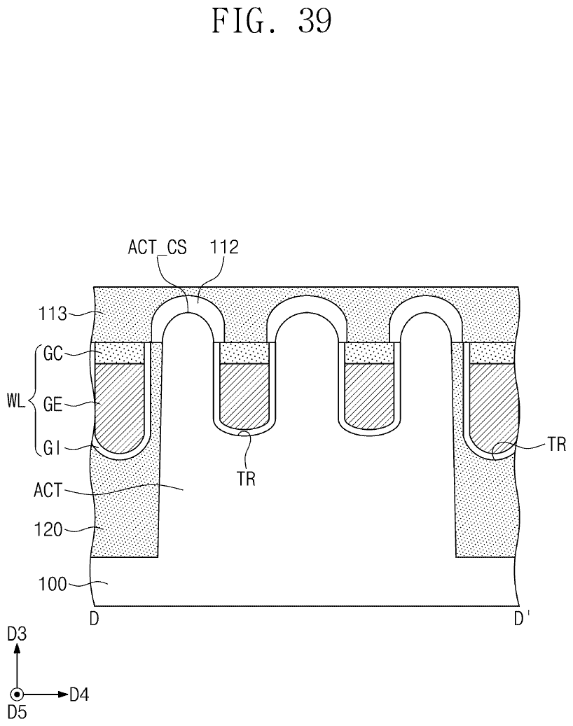

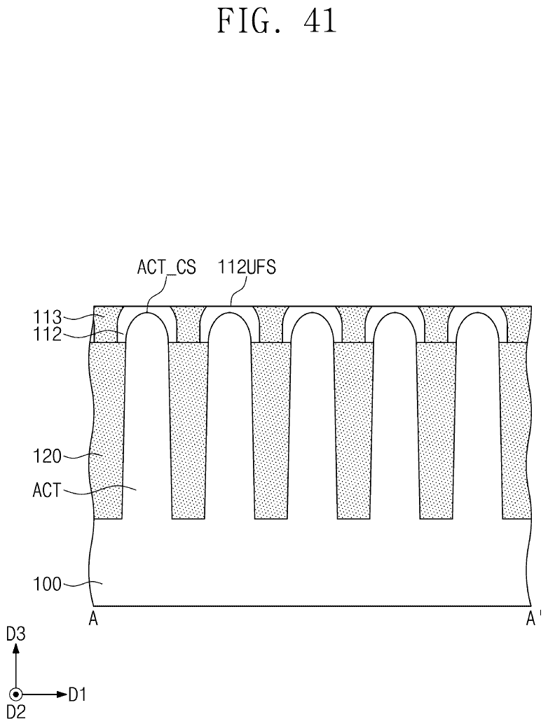

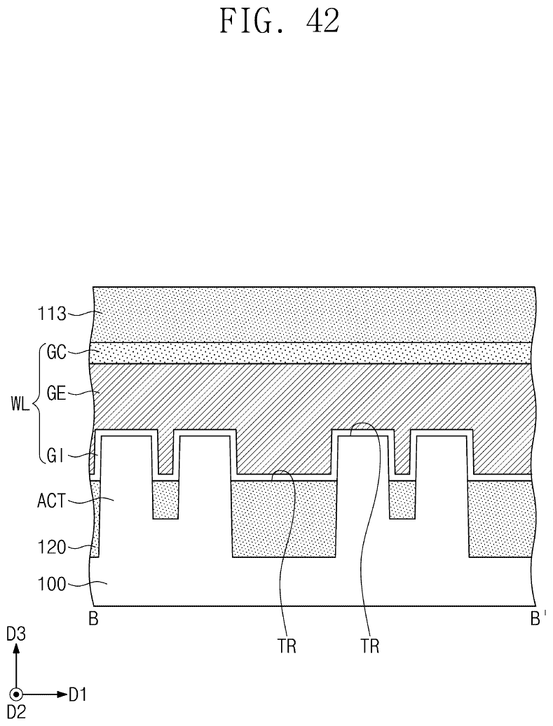

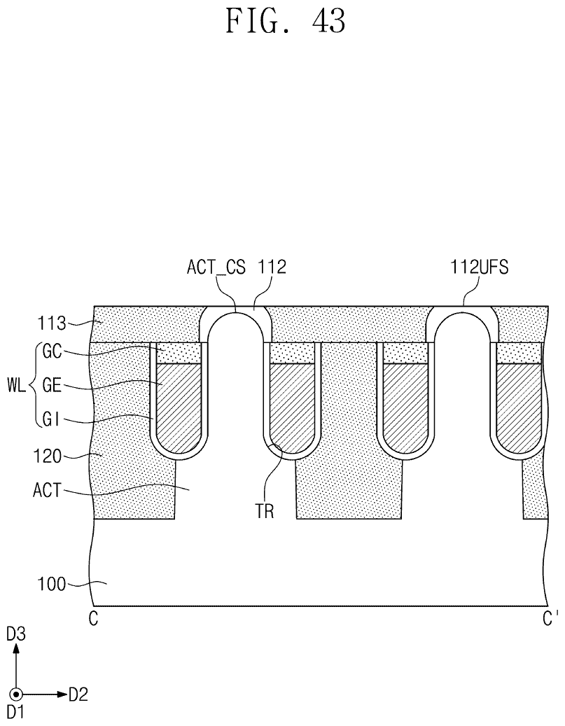

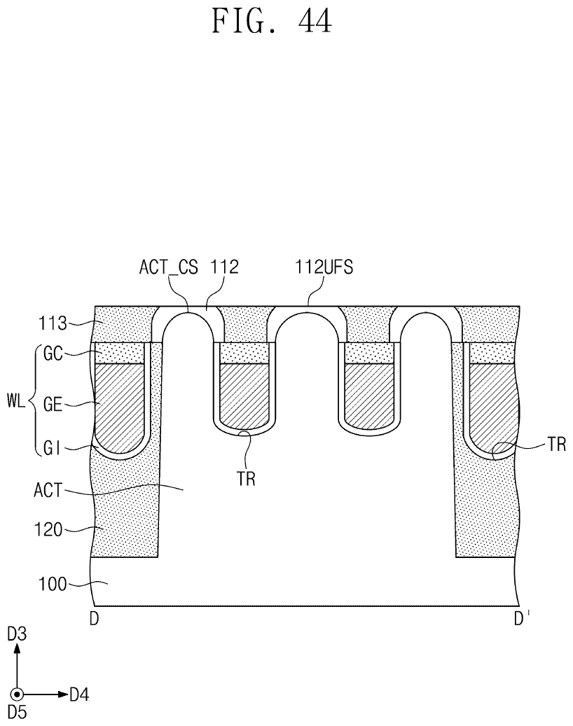

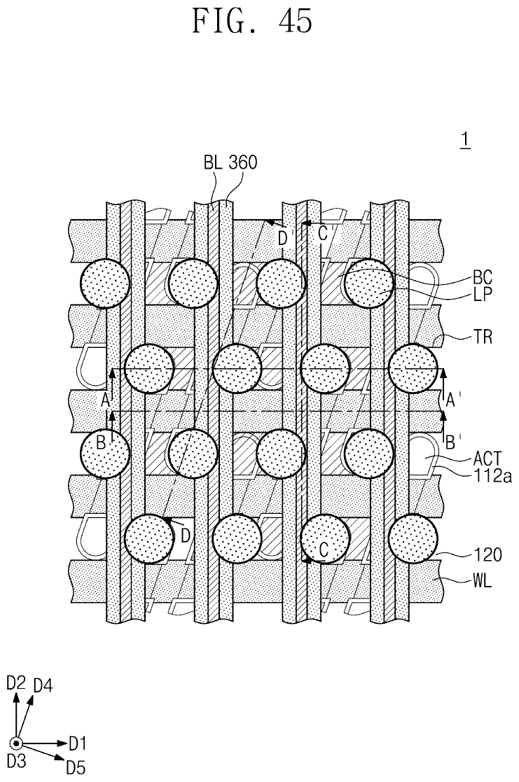

FIGS. 10, 15, 20, 25, 30, 35, and 40 illustrate plan views showing a method of fabricating a semiconductor device according to some example embodiments of the present inventive concepts. FIGS. 11, 16, 21, 26, 31, 36, and 41 illustrate cross-sectional views taken along line A-A′ of FIGS. 10, 15, 20, 25, 30, 35, and 40, respectively. FIGS. 12, 17, 22, 27, 32, 37, and 42 illustrate cross-sectional views taken along line B-B′ of FIGS. 10, 15, 20, 25, 30, 35, and 40, respectively. FIGS. 13, 18, 23, 28, 33, 38, and 43 illustrate cross-sectional views taken along line C-C′ of FIGS. 10, 15, 20, 25, 30, 35, and 40, respectively. FIGS. 14, 19, 24, 29, 34, 39, and 44 illustrate cross-sectional views taken along line D-D′ of FIGS. 10, 15, 20, 25, 30, 35, and 40, respectively. For brevity of description, a repetitive description will be omitted.

Referring to FIGS. 10 to 14, a substrate 100 may be provided. The substrate 100 may be a semiconductor substrate, for example, one of a silicon substrate, a germanium substrate, and a silicon-germanium substrate.

Active patterns ACT may be formed on the substrate 100. Each of the active patterns ACT may have a linear, or substantially linear, shape that extends in a fourth direction D4. The fourth direction D4 may intersect a first direction D1 and a second direction D2. For example, the fourth direction D4 may be parallel or substantially parallel to a plane defined by the first direction D1 and the second direction D2. The active patterns ACT may be defined to indicate upper portions of the substrate 100 that protrude in a third direction D3. The third direction D3 may intersect the first direction D1, the second direction D2, and the fourth direction D4. For example, the third direction D3 may be perpendicular to the first direction D1, the second direction D2, and the fourth direction D4. The active patterns ACT may be spaced apart from each other.

A device isolation pattern 120 may be formed in a space provided between the active patterns ACT and may be buried in an upper portion of the substrate 100. The formation of the device isolation pattern 120 may include employing a patterning process to partially remove an upper portion of the substrate 100, and filling the removed portion with the device isolation pattern 120. The device isolation pattern 120 may be a single layer including one material or a multiple layer including two or more materials.

The active patterns ACT may be defined by the device isolation pattern 120. Each of the active patterns ACT may be surrounded by the device isolation pattern 120. The device isolation pattern 120 may separate the active patterns ACT from each other.

A mask pattern MP may be formed on the active patterns ACT and the device isolation pattern 120. The mask pattern MP may include linear patterns that extend in the first direction D1 and are spaced apart from each other in the second direction D2. For example, the mask pattern MP may run in the first direction D1 across the active patterns ACT and the device isolation pattern 120. Mask trenches MTR may be formed between the linear patterns of the mask pattern MP. The mask trenches MTR may extend in the first direction D1 and may be spaced apart from each other in the second direction D2.

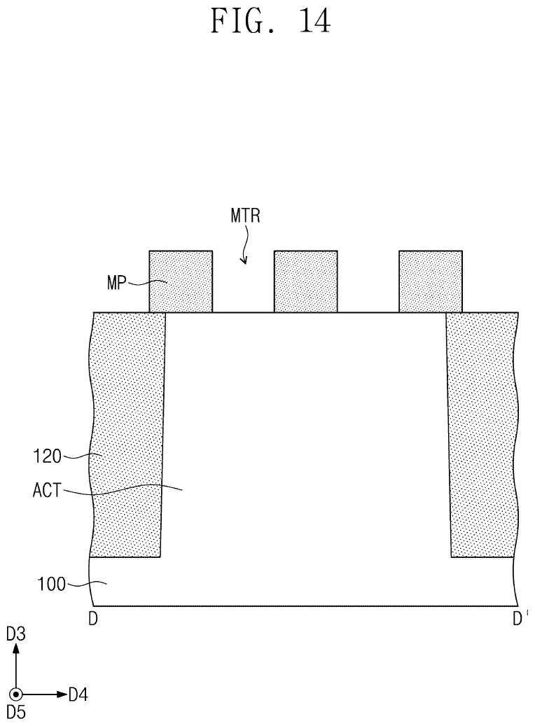

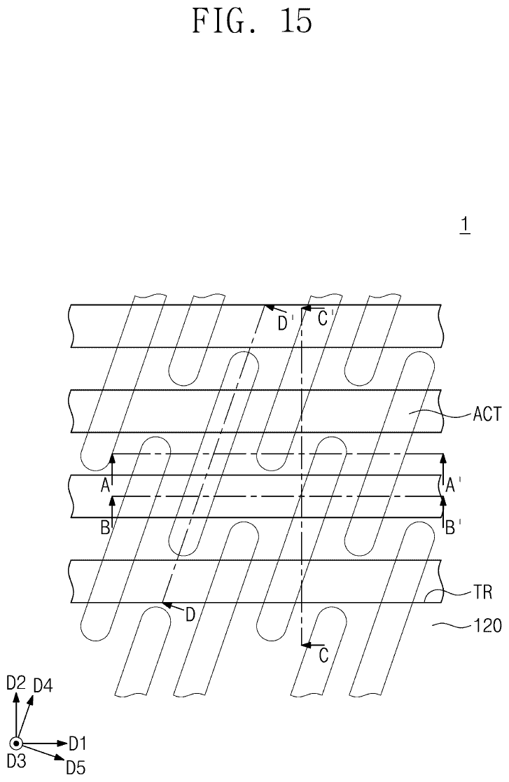

Referring to FIGS. 15 to 19, an etching process may be performed in which the mask pattern MP may be used as an etching mask to etch upper portions of the active patterns ACT and an upper portion of the device isolation pattern 120. Therefore, trenches TR may be formed on regions that at least partially vertically overlap the mask trenches MTR of the mask pattern MP. The trenches TR may extend in the first direction D1 and may be spaced apart from each other in the second direction D2. For example, a pair of trenches TR that neighbor each other in the second direction D2 may run in the first direction D1 across each of the active patterns ACT.

Each of the trenches TR may have an uneven structure on a bottom surface thereof. For example, the trench TR may be provided in plural, and the plurality of trenches TR may be formed at different levels from each other. The trench TR formed on the active pattern ACT may have a bottom surface at a level different or substantially different from that of a bottom surface of the active pattern ACT formed on the device isolation pattern 120. When the etching process is performed, the active pattern ACT and the device isolation pattern 120 may have different etch rates, and thus the trenches TR may have their bottom surfaces at different levels from each other.

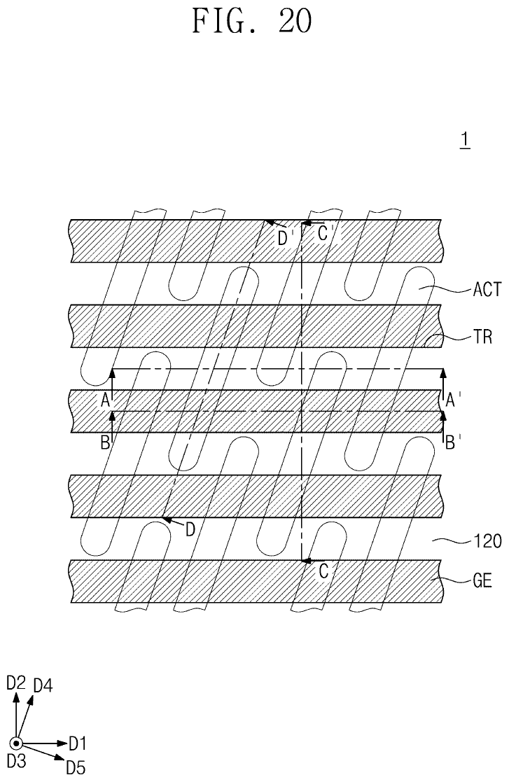

Referring to FIGS. 20 to 24, a gate dielectric pattern GI may be conformally formed on an entire surface of the substrate 100. For example, the gate dielectric pattern GI may be conformally formed in the trenches TR, and may extend onto top surfaces of the active patterns ACT and a top surface of the device isolation pattern 120. The gate dielectric pattern GI may have on its bottom surface an uneven structure along the trench TR. The gate dielectric pattern GI may be formed by physical vapor deposition (PVD), chemical vapor deposition (CVD), or atomic layer deposition (ALD). The gate dielectric pattern GI may include at least one of silicon oxide, high-k dielectrics, or any combination thereof.

Thereafter, a gate electrode GE may be formed in the trench TR. A plurality of gate electrodes GE may be correspondingly formed in the trenches TR. The gate electrodes GE may be formed on the gate dielectric pattern GI. The gate electrode GE may include a conductive material. A lower portion of the trench TR in which the gate dielectric pattern GI is formed may be filled with a conductive material to form the gate electrode GE. The gate electrode GE may be a single or multiple layer including metal, metal nitride, impurity-doped polysilicon, or any combination thereof.

The trench TR may have a remaining portion in which the gate electrode GE is not formed, and the remaining portion of the trench TR may be filled with a dielectric material to form a gate capping pattern GC. The gate capping pattern GC may be formed on the gate electrode GE. The formation of the gate capping pattern GC may include forming a gate capping layer (not shown) that at least partially fills an occupied portion of the trench TR and at least partially covers at least one of the top surfaces of the active patterns ACT and the top surface of the device isolation pattern 120, and removing an upper portion of the gate capping layer to form the gate capping pattern GC. The gate electrode GE, the gate dielectric pattern GI, and the gate capping pattern GC may constitute a gate structure WL. The gate structure WL may be formed, for example, in the trench TR.

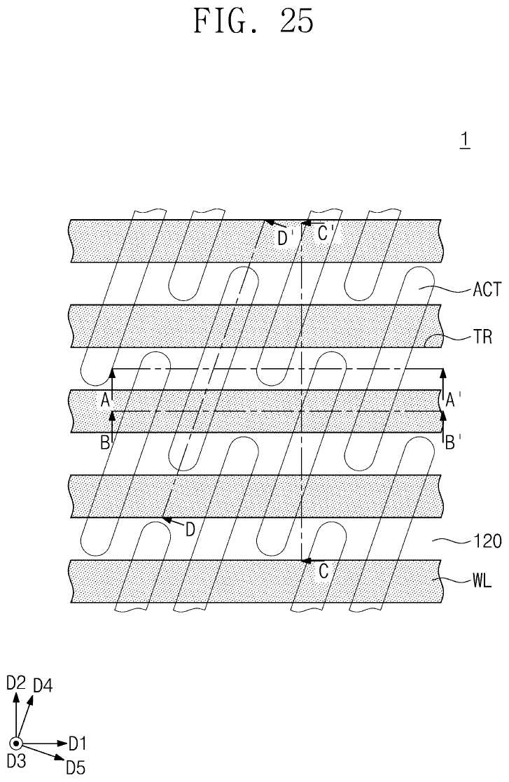

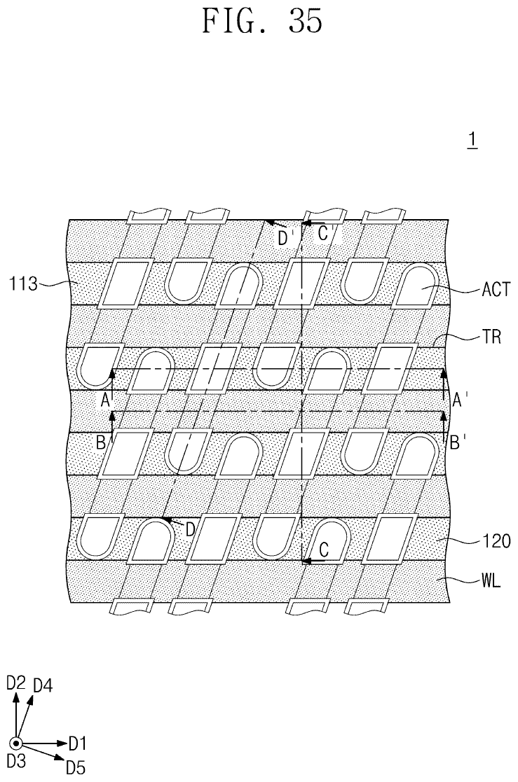

Referring to FIGS. 25 to 29, the gate dielectric pattern GI, the gate capping pattern GC, and the device isolation pattern 120 may be partially etched. The gate dielectric pattern GI, the gate capping pattern GC, and the device isolation pattern 120 may be etched to a level of a bottom surface of an additional capping layer 113 which will be discussed below with reference to FIGS. 35 to 39. In this case, because only a portion of the active pattern ACT is etched to form a curved surface ACT_CS and a remaining portion of the active pattern ACT remains without being etched, and, because only the gate dielectric pattern GI, the gate capping pattern GC, and the device isolation pattern 120 are etched, there may be a difference or differences in level between an uppermost portion UM at the top surface of the active pattern ACT, a top surface of the gate dielectric pattern GI, a top surface of the gate capping pattern GC, and the top surface of the device isolation pattern 120.

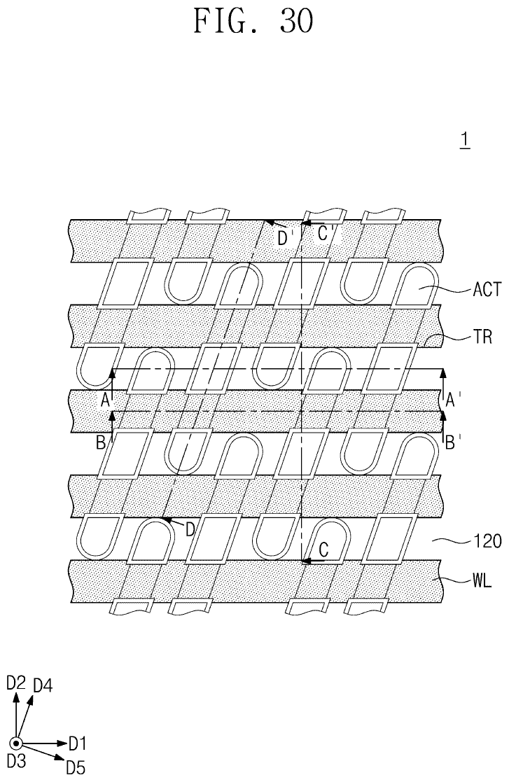

Referring to FIGS. 30 to 34, an additional active layer 112 may be formed on the active pattern ACT. The additional active layer 112 may be formed to at least partially cover the active pattern ACT. The additional active layer 112 may include a material the same as that of the active pattern ACT. The additional active layer 112 may be formed by, for example, selective epitaxial growth (SEG). As the additional active layer 112 is formed on an exposed surface of the active pattern ACT, the additional active layer 112 may be formed at a level higher than that of the top surface of the device isolation pattern 120, that of the top surface of the gate capping pattern GC, and that of the top surface of the gate dielectric pattern GI. As the additional active layer 112 is formed on the exposed surface of the active pattern ACT, the additional active layer 112 may have a curved or substantially curved surface.

Referring to FIGS. 35 to 39, an additional capping layer 113 may be formed on the additional active layer 112, the gate capping pattern GC, the gate dielectric pattern GI, and the device isolation pattern 120. The additional capping layer 113 may be formed on the device isolation pattern 120, the additional active layer 112, the gate capping pattern GC, and the gate dielectric pattern GI.

The additional capping layer 113 may include a material the same as that of the gate capping pattern GC. The additional capping layer 113 may include a material the same as that of the device isolation pattern 120. Although the additional capping layer 113 includes a material the same as that of the gate capping pattern GC or the device isolation pattern 120, because there may be a time interval between the formation of the additional capping layer 113 and the etching of the gate capping pattern GC or the device isolation pattern 120, an interface may be formed between the additional capping layer 113 and the gate capping pattern GC or the device isolation pattern 120.

The formation of the additional capping layer 113 may define the contact points CP1 and CP2 discussed above.

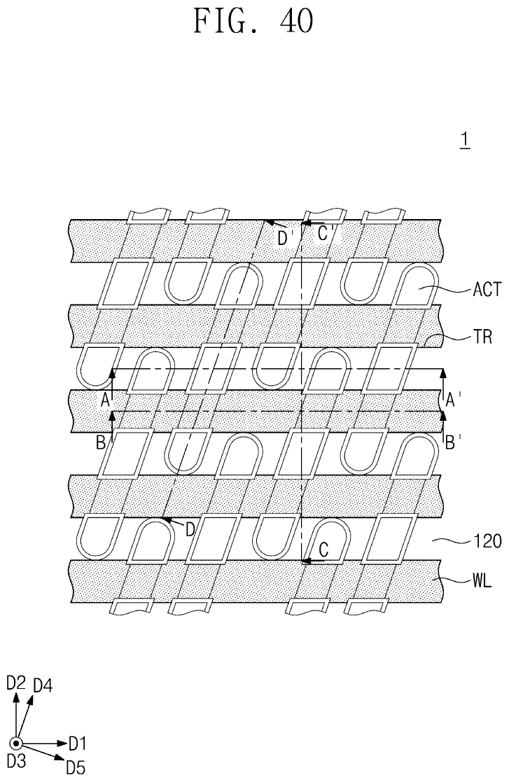

Referring to FIGS. 40 to 44, a portion of the additional capping layer 113 may be etched. The additional capping layer 113 may be etched to a level the same as that of an upper flat surface 112UFS of the additional active layer 112. When the additional capping layer 113 is etched, a portion of the additional active layer 112 may also be etched. When the additional capping layer 113 is etched, the additional capping layer 113 and the additional active layer 112 may be removed to the same level. Therefore, the additional capping layer 113 may be removed until a top surface of the additional capping layer 113 is located at a level the same as that of an upper flat surface 112UFS of the additional active layer 112.

Referring back to FIGS. 1 to 5, a buffer layer (not shown) and a polysilicon layer (not shown) may be formed to at least partially cover at least one of the active patterns ACT and the device isolation pattern 120, and a first recess RS1 may be formed on each of the active patterns ACT, the additional active layer 112, and the additional capping layer 113. In this step, the buffer layer and the polysilicon layer may be partially removed to form a buffer pattern 210 and an intervening pattern 310. For example, the buffer pattern 210 may include at least one of silicon oxide, silicon nitride, silicon oxynitride, or any combination thereof. For example, the intervening pattern 310 may include polysilicon.

A bit-line contact DC, a bit line BL, and a bit-line capping pattern 350 may be formed on the first recess RS1. The formation of the bit-line contact DC, the bit line BL, and the bit-line capping pattern 350 may include forming a bit-line contact layer (not shown) to fill the first recess RS1, sequentially forming a bit line layer (not shown) and a bit-line capping layer (not shown) on the bit-line contact layer, and etching the bit-line contact layer, the bit line layer, and the bit-line capping layer to form the bit-line contact DC, the bit line BL, and the bit-line capping pattern 350. In this step, a partial inside portion of the first recess RS1 may be outwardly exposed again. After that, a buried dielectric pattern 250 may be formed to fill an unoccupied portion of the first recess RS1. For example, the bit-line contact DC may include polysilicon. The bit line BL may include at least one of tungsten, rubidium, molybdenum, titanium, or any combination thereof. For example, the bit-line capping pattern 350 may include silicon nitride. During the formation of the bit line BL, a first ohmic pattern 320 may further be formed between the bit line BL and the bit-line contact DC and between the bit line BL and the intervening pattern 310. The first ohmic pattern 320 may include, for example, metal silicide.

A bit-line spacer 360 may be formed to at least partially cover a at least one of the lateral surface of the bit line BL and a lateral surface of the bit-line capping pattern 350. The formation of the bit-line spacer 360 may include sequentially forming a first spacer 362, a second spacer 364, and a third spacer 366 that at least partially conformally cover the lateral surface of the bit line BL and the lateral surface of the bit-line capping pattern 350. For example, the first, second, and third spacers 362, 364, and 366 may each include at least one of silicon nitride, silicon oxide, silicon oxynitride, or any combination thereof. For another example, the second spacer 364 may include a kind of air gap that separates the first and third spacers 362 and 366 from each other.

Storage node contacts BC and fence patterns FN may be formed between neighboring bit lines BL. The storage node contacts BC and the fence patterns FN may be alternately arranged along the second direction D2. Each of the storage node contacts BC may fill a second recess RS2, and may be electrically connected to the active pattern ACT that corresponds to the second recess RS2. The fence patterns FN may be formed at positions that at least partially vertically overlap the gate structures WL. For example, the storage node contacts BC may be formed, and thereafter the fence patterns FN may be formed between the storage node contacts BC. For another example, the fence patterns FN may be formed, and thereafter the storage node contacts BC may be formed between the fence patterns FN. The storage node contacts BC may include, for example, at least one of impurity-doped polysilicon, impurity-undoped polysilicon, metal, or any combination thereof. The fence patterns FN may include, for example, silicon nitride.

During the formation of the storage node contacts BC, an upper portion of the bit-line spacer 360 may be partially removed. Therefore, a capping spacer 370 may further be formed at a position where the bit-line spacer 360 is removed. For example, the capping spacer 370 may include silicon nitride. Afterwards, a second barrier pattern 410 may be formed to at least partially conformally cover the bit-line spacer 360, the capping spacer 370, and the storage node contacts BC. The second barrier pattern 410 may include, for example, conductive metal nitride.

Landing pads LP may be formed on the storage node contacts BC. The formation of the landing pads LP may include, for example, sequentially forming a landing pad layer (not shown) and mask patterns (not shown) that at least partially cover top surfaces of the storage node contacts BC, and using the mask patterns as an etching mask to perform an anisotropic etching process to separate the landing pad layer into a plurality of landing pads LP. The second barrier pattern 410, the bit-line spacer 360, and the bit-line capping pattern 350 may further be partially etched and outwardly exposed. An upper portion of the landing pad LP may be shifted in the first direction D1 from the storage node contact BC. For example, the landing pad LP may include a metallic material, such as tungsten, titanium, and tantalum.

According to some example embodiments, the etching process of the landing pad layer may expose the second spacer 364. The etching process of the second spacer 364 may further be performed on the exposed portion of the second spacer 364, and eventually the second 364 may include an air gap. Example embodiments, however, are not limited thereto.

After the etching process, a filling pattern 440 may be formed to at least partially cover exposed portions of the landing pads LP and to surround each of the landing pads LP, and a data storage pattern DSP may be formed on each of the landing pads LP.

The data storage pattern DSP may be, for example, a capacitor including a bottom electrode, a dielectric layer, and a top electrode. In this case, a semiconductor memory device according to some example embodiments may be a dynamic random access memory (DRAM). For another example, the data storage pattern DSP may include a magnetic tunnel junction pattern. In this case, a semiconductor memory device according to some example embodiments may be a magnetic random access memory (MRAM). For another example, the data storage pattern DSP may include a phase change material or a variable resistance material. In this case, a semiconductor memory device according to the some example embodiments may be a phase change random access memory (PRAM) or a resistive random access memory (ReRAM). This is, however, merely an example, and example embodiments of the inventive concepts are not limited thereto. The data storage pattern DSP may include various structures and/or materials capable of storing data.

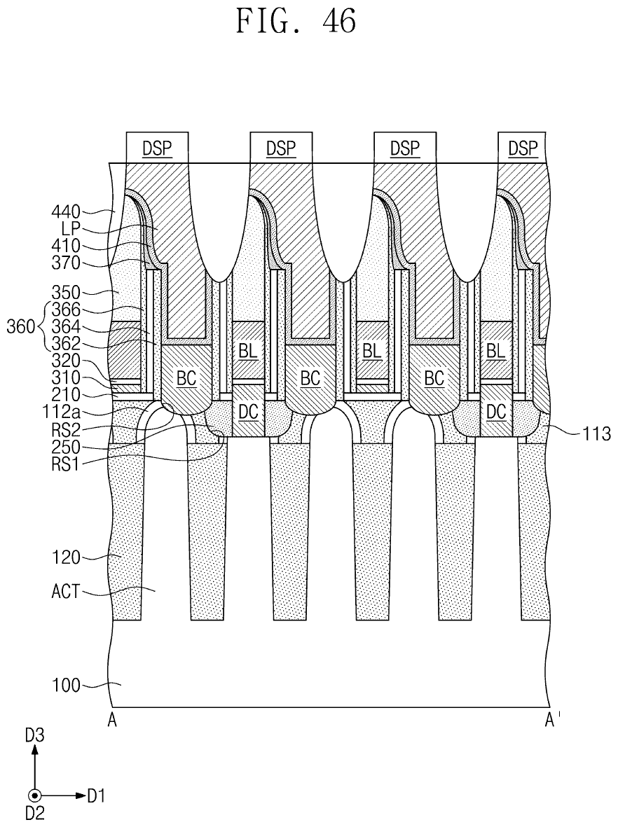

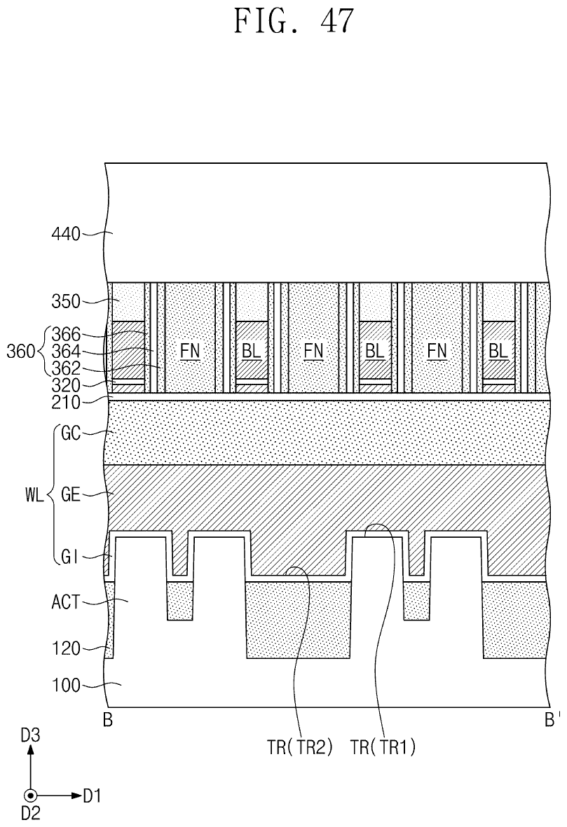

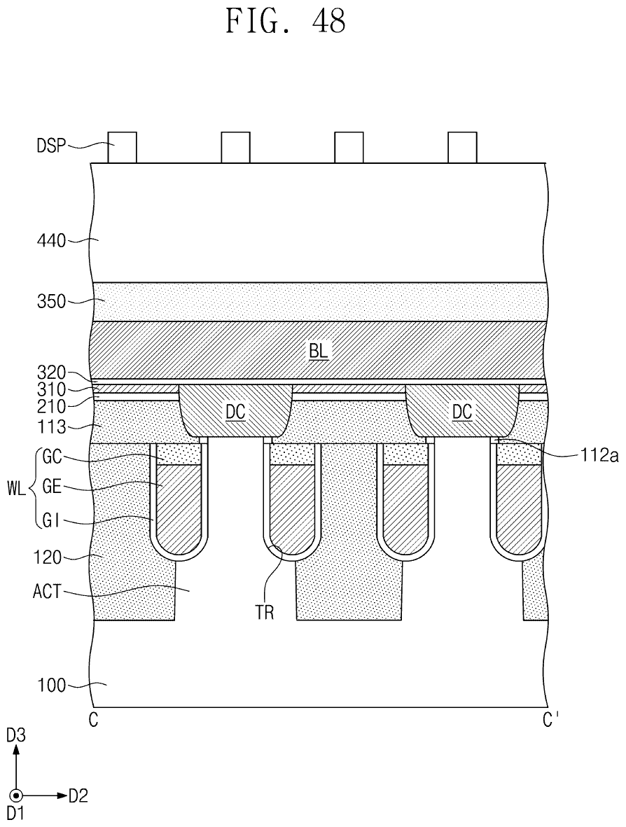

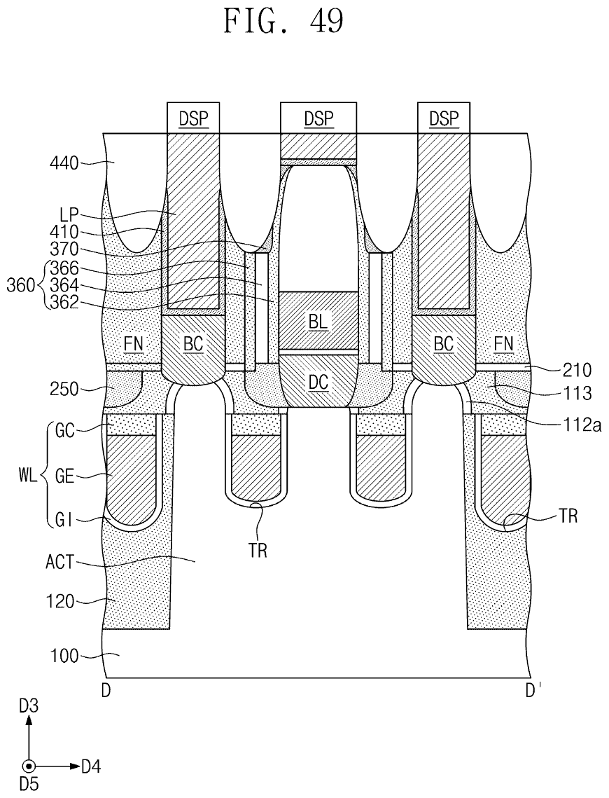

FIG. 45 illustrates a plan view showing a semiconductor device according to some example embodiments of the present inventive concepts. FIG. 46 illustrates a cross-sectional view taken along line A-A′ of FIG. 45. FIG. 47 illustrates a cross-sectional view taken along line B-B′ of FIG. 45. FIG. 48 illustrates a cross-sectional view taken along line C-C′ of FIG. 45. FIG. 49 illustrates a cross-sectional view taken along line D-D′ of FIG. 45. For brevity of description, a repetitive description will be omitted.

Referring to FIGS. 45 to 49, in an example embodiment, a lowermost portion of an additional active layer 112a may be located at a level lower than that the lowermost portion of the bit-line contact DC. In this case, the additional active layer 112a may be in contact with the bit-line contact DC as well as the storage node contact BC.

In the procedure of partially etching the gate dielectric pattern GI, the gate capping pattern GC, and the device isolation pattern 120 discussed above in FIGS. 25 to 29, the gate dielectric pattern GI, the gate capping pattern GC, and the device isolation pattern 120 may be etched to a level lower than that at which the first recesses RS1 will be formed, and thereafter the additional active layer 112a may be formed. In this case, the lowermost portion of the additional active layer 112a may be located at a level lower than that of the lowermost portion of the bit-line contact DC. In this case, an interface formed between the gate capping pattern GC and the additional capping layer 113 may be located at a level lower than that of the lowermost portion of the bit-line contact DC.

According to some example embodiments, as an additional active layer is included on an active pattern, the additional active layer may allow a storage node contact to make contact with the active pattern through an increases contact surface, and as the additional active layer is formed only on an upper portion of the active pattern, no material may separately remain on a lower portion of the active pattern to reduce process failure and to increase reliability of the semiconductor device.

The aforementioned description provides some example embodiments for explaining the present inventive concepts. Therefore, the present inventive concepts are not limited to the example embodiments described above, and it will be understood by one of ordinary skill in the art that variations in form and detail may be made therein without departing from the spirit and essential features of the present inventive concepts.

What is claimed is:

1. A semiconductor device, comprising:
an active pattern;
an additional active layer on the active pattern; and
a gate structure running across the active pattern, wherein
the additional active layer includes
a bottom surface connected to a sidewall of the active pattern; and
an upper curved surface above the bottom surface, and
a lattice constant of the additional active layer is different from a lattice constant of the active pattern.

2. The semiconductor device of claim 1, wherein
the gate structure includes a gate dielectric pattern, and
a lowermost portion of the additional active layer is in contact with the gate dielectric pattern.

3. The semiconductor device of claim 1, further comprising:
a device isolation pattern defining the active pattern, wherein
the active pattern includes
a first active part at least partially overlapping the gate structure; and
a second active part at least partially overlapping the device isolation pattern.

4. The semiconductor device of claim 3, wherein
the first active part has a tetragonal shape when viewed in plan, and
the second active part includes a curved portion when viewed in plan.

5. The semiconductor device of claim 1, wherein
the gate structure includes a gate electrode and a gate capping pattern on the gate electrode, and
the semiconductor device further comprises an additional capping layer in contact with the additional active layer and the gate capping pattern.

6. The semiconductor device of claim 1, wherein
the gate structure includes a gate dielectric pattern, and
a top surface of the gate dielectric pattern is below an uppermost portion of the active pattern.

7. The semiconductor device of claim 1, wherein the active pattern and the additional active layer are a single unitary body with no interface therebetween.

8. The semiconductor device of claim 1, further comprising:
a storage node contact in contact with the active pattern, wherein
a lowermost portion of the additional active layer is below a lowermost portion of the storage node contact.

9. The semiconductor device of claim 1, further comprising:
a device isolation pattern defining the active pattern; wherein
a contact point of the sidewall of the active pattern and the additional active layer is planar with a lowermost portion of the additional active layer.

10. A semiconductor device, comprising:
an active pattern;
an additional active layer on the active pattern; and
a storage node contact in contact with the additional active layer and the active pattern, wherein
the additional active layer includes
a bottom surface connected to a sidewall of the active pattern;
an upper curved surface above the bottom surface;
a lateral surface between the bottom surface and the upper curved surface, and
a first contact point contacting the sidewall of the active pattern and below a lowermost portion of the storage node contact.

11. The semiconductor device of claim 10, further comprising:
a gate structure that runs across the active pattern, wherein
the gate structure includes a gate dielectric pattern, and
the gate dielectric pattern and the additional active layer at least partially overlap each other.

12. The semiconductor device of claim 11, further comprising:
an additional capping layer, the additional capping layer at least partially covering at least one of the upper curved surface of the additional active layer, the lateral surface of the additional active layer, and a top surface of the gate dielectric pattern.

13. The semiconductor device of claim 12, wherein the first contact point is planar with a bottom surface of the additional capping layer.

14. The semiconductor device of claim 11, further comprising:
a device isolation pattern defining the active pattern, wherein
the first contact point contacts the device isolation pattern, and
the additional active layer further includes a second contact point contacting the gate dielectric pattern.

15. The semiconductor device of claim 10, further comprising:
a gate structure running across the active pattern; and
an additional capping layer at least partially covering at least one of the upper curved surface and the lateral surface of the additional active layer, wherein
the gate structure includes
a gate dielectric pattern;
a gate electrode on the gate dielectric pattern; and
a gate capping pattern on the gate electrode, and
a bottom surface of the additional capping layer contacts a top surface of the gate dielectric pattern.

16. The semiconductor device of claim 10, wherein a lattice constant of the additional active layer is different from a lattice constant of the active pattern.

17. The semiconductor device of claim 10, wherein the additional active layer at least partially surrounds the active pattern when viewed in plan.

18. The semiconductor device of claim 10, further comprising:
a bit-line contact connected to the active pattern, wherein
the first contact point is below a lowermost portion of the bit-line contact.

19. A semiconductor device, comprising:
an active pattern;
an additional active layer on the active pattern;
a device isolation pattern surrounding the active pattern; and
a storage node contact electrically connected to the additional active layer, wherein
the additional active layer includes a bottom surface connected to a sidewall of the active pattern,
a contact point of the bottom surface of the additional active layer is below a lowermost portion of the storage node contact, and
a lattice constant of the additional active layer is different from a lattice constant of the active pattern.

20. The semiconductor device of claim 19, further comprising:
an additional capping layer at least covering at least one of an upper curved surface and a lateral surface of the additional active layer; and
a gate structure running across the active pattern, wherein
the gate structure includes a gate capping pattern,
the additional active layer includes a material that is the same as a material of the active pattern, and
the additional capping layer includes a material that is the same as a material of the gate capping pattern.
